(19) United States
(12) Patent Application Publication
(10) Pub. No.: US 2014/0127494 A1
(43) Pub. Date: May 8, 2014

(54) POLYIMIDE POROUS BODY AND METHOD FOR PRODUCING SAME

(71) Applicants: Shinpei Yakuwa, Ibaraki-shi (JP); Takeshi Sutou, Ibaraki-shi (JP); Keiko Akiyama, Ibaraki-shi (JP); Kiichiro Matsushita, Ibaraki-shi (JP)

(72) Inventors: Shinpei Yakuwa, Ibaraki-shi (JP); Takeshi Sutou, Ibaraki-shi (JP); Keiko Akiyama, Ibaraki-shi (JP); Kiichiro Matsushita, Ibaraki-shi (JP)

(73) Assignee: NITTO DENKO CORPORATION, Ibaraki-shi, Osaka (JP)

(21) Appl. No.: 14/123,695

(22) PCT Filed: May 28, 2012
(86) PCT No.: PCT/JP2012/063633

§ 371 Date: Dec. 3, 2013

(30) Foreign Application Priority Data
Jun. 6, 2011 (JP) 2011-126214
Apr. 25, 2012 (JP) 2012-100163

(51) Int. Cl. C08J 9/28; H05K 1/03

(52) U.S. Cl. CPC C08J 9/28; H05K 1/0346
USPC 428/315.7; 428/304.4; 427/373

(57) ABSTRACT

An object of the present invention is to provide a polyimide porous body having an excellent heat resistance, a fine cell structure, and a low relative dielectric constant, and a method for producing the polyimide porous body. The present invention relates to a method for producing a polyimide porous body, comprising a step for applying a polymer solution containing a polyamide acid, a phase separation agent for separating the phases of the polyamide acid, an imidization catalyst, and a dehydrating agent, on a substrate, and drying the polymer solution to produce a phase-separated structure body having a microphase-separated structure; a step for producing a porous body by removing the phase separation agent from the phase-separated structure body; and a step for subjecting the polyamide acid in the porous body to imidization to synthesize a polyimide.

### TECHNICAL FIELD

The present invention relates to a polyimide porous body having a fine cell, a low relative dielectric constant, and an excellent heat resistance, and a method for producing the polyimide porous body. For example, the polyimide porous body of the present invention is suitably used for a circuit board of electronic devices.

### BACKGROUND ART

Because of their high insulating properties, plastic films have conventionally been utilized as parts or members required to have reliability, such as circuit boards, printed circuit boards, etc., in electronic/electrical devices, electronic parts, etc. In the field of electrical devices where a large quantity of information is stored, processed, and transmitted at a high speed, associated with the recent higher performances and higher functions in the electronic/electrical devices, plastic materials for use therein are also required to have higher performances. In particular, a lower dielectric constant and a lower dielectric loss tangent are desired as electrical properties particularly responding to higher frequencies.

Since the relative dielectric constant of a plastic material is generally determined by the molecular structure thereof, a method for modifying a molecular structure is considered as an approach to reduce the relative dielectric constant. However, there is a limit to reduce the relative dielectric constant even if the molecular structure is modified.

There is another attempt to reduce dielectric constant by making a plastic material porous to thereby control its relative dielectric constant based on the porosity thereof, with taking advantage of the relative dielectric constant of air, which is 1.

Conventionally known common methods used for producing a porous body include a dry method and a wet method, and the dry method includes a physical method and a chemical method. The general physical method comprises dispersing a low-boiling liquid (foaming agent) such as a chlorofluorocarbon or a hydrocarbon into a polymer and then heating the dispersion to volatilize the foaming agent and thereby to form cells. In addition, the chemical method for obtaining cells comprises adding a foaming agent to a polymer and pyrolyzing the mixture to generate a gas and thereby to form cells.

For example, Patent Document 1 proposes a method for obtaining a foamed polyetherimide using methylene chloride, chloroform, trichloroethane, or the like as a foaming agent.

Further, in recent years, a method for obtaining cells having a small pore size and a high cell density has been proposed.

This method comprises dissolving a gas such as nitrogen or carbon dioxide in a polymer at high pressure, subsequently releasing the polymer from the pressure, and heating the polymer to around the glass transition temperature or softening point thereof to thereby form cells. This foaming technique, in which cells are formed by forming nuclei from the thermodynamically unstable state and then expanding and growing the nuclei, has an advantage such that a microporous foam which has been unobtainable so far can be obtained.

For example, Patent Document 2 proposes to obtain a heat-resistant foam by applying the method described above to a polyetherimide. In addition, Patent Document 3 proposes to obtain a foam having closed cells with an average cell size of from 0.1 to 20 μm by applying the above-mentioned method to a styrene-based resin having a syndiotactic structure. Further, Patent Document 4 proposes a low dielectric constant insulating plastic film which comprises a porous plastic having a porosity of 10 vol % or higher obtained using carbon dioxide or the like as a foaming agent, a heat resistance temperature of 100° C. or more, and a dielectric constant of 2.5 or less.

However, it has been pointed out that the physical methods mentioned above have environmental influences, such as harmfulness of the substances used as foaming agents and ozone layer depletion caused by such substances. In addition, it is difficult to obtain a foam having fine cells uniform in size by the physical method, although such a method is generally suitable for obtaining a foam having an average pore size of tens of micrometers or larger.

On the other hand, the chemical method is unsuitable for use in electronic/electrical devices, electronic parts, etc., where pollution reduction is highly required, because a residue of the foaming agent which has generated a gas remains in the resulting foam after foaming.

In addition, in the method described in Patent Document 2, this method has the following drawback. When a polymer is impregnated with a high-pressure gas in a pressure vessel, the pressure vessel is heated to or around the Vicat softening point of the polymer. Because of this heating, the polymer is in a molten state during pressure reduction and, hence, the high-pressure gas readily expands. As a result, the cell size of the obtained foam does not become small too much. Consequently, this foam, for example, when intended to be used as a circuit substrate, becomes thick and imposes limits on the formation of finer patterns.

In order to solve the above problems, there has been proposed a method for obtaining a porous body having an extremely fine cell and a low dielectric constant by adding an additive to a polymer such as polyimide with heat resistance to forma specific microphase-separated structure, and removing the additive with a solvent extraction method and a heating method utilizing the differences of both components in the volatility (boiling point), pyrolysis, or solubility in solvents. For example, Patent Document 5 proposes a method for producing a porous polyimide, which comprises removing a dispersible compound B from the polymer composition having a microphase-separated structure composed of a continuous phase comprising a polyimide precursor A and a discontinuous phase, dispersed therein, comprising the dispersible compound B having an average size of less than 10 μm, and converting the polyimide precursor A into a polyimide.

### PRIOR ART DOCUMENTS

### Patent Documents

Patent Document 1: U.S. Pat. No. 4,532,263

Patent Document 2: JP-A-6-322168

Patent Document 3: JP-A-10-45936

Patent Document 4: JP-A-9-100363

Patent Document 5: JP-A-2002-146085

### SUMMARY OF THE INVENTION

### Problems to be Solved by the Invention

An object of the present invention is to provide a polyimide porous body having an excellent heat resistance, a fine cell structure, and a low relative dielectric constant, and a method for producing the polyimide porous body. Furthermore, it is another object to provide a polyimide porous body having extremely fine pore sizes so as to minimize reductions in mechanical strength and insulating properties specific to porous bodies, and a method for producing the polyimide porous body.

### Means for Solving the Problems

That is, the present invention relates to a method for producing a polyimide porous body, comprising a step for applying a polymer solution containing a polyamide acid, a phase separation agent for separating the phases of the polyamide acid, an imidization catalyst, and a dehydrating agent, on a substrate, and drying the polymer solution to produce a phase-separated structure body having a microphase-separated structure; a step for producing a porous body by removing the phase separation agent from the phase-separated structure body; and a step for subjecting the polyamide acid in the porous body to imidization to synthesize a polyimide.

The present inventors have found that the pore size of the polyimide porous body can be reduced by adding an imidization catalyst and a dehydrating agent to a polymer solution containing polyamide acid and a phase separation agent for separating the phases of the polyamide acid, and thereby to be able to improve the mechanical strength and insulating properties of the polyimide porous body. Generally, polyimides are insoluble in an organic solvent and they are a polymer that is difficult in molding. Therefore, in the present invention, there is employed a method of producing a polyimide porous body by forming a porous body using, as a raw material, a polyamide acid that is a precursor of the polyimide, and subjecting the polyamide acid to imidization, thereby to synthesize a polyimide.

The phase separation agent in the phase-separated structure body is preferably removed by solvent extraction or heating, and the solvent to be used preferably includes liquefied carbon dioxide, subcritical carbon dioxide, or supercritical carbon dioxide.

The temperature in the synthesis of polyimides by imidization of a polyamide acid is 300 to 400° C.

The polyimide porous body produced by the method of the present invention has preferably an average pore size of 0.1 to 10 μm, a volume porosity of 20 to 90%, and a relative dielectric constant of 1.4 to 2.0.

In addition, the polyimide porous substrate of the present invention has a metal foil on at least one side of the polyimide porous body.

### Effect of the Invention

The polyimide porous body of the present invention has features of having excellent heat resistance because it is formed of polyimide and having excellent mechanical strength and insulating properties because it has a fine cell structure, as well as having a lower relative dielectric constant. Therefore, the polyimide porous body of the present invention is suitably used as circuit boards, printed circuit boards, etc. for electronic/electrical devices, electronic parts, etc.

### MODE FOR CARRYING OUT THE INVENTION

Hereinafter, the embodiments of the present invention will be described.

The method for producing a polyimide porous body according to the present invention comprises a step for applying a polymer solution containing a polyamide acid, a phase separation agent for separating the phases of the polyamide acid, an imidization catalyst, and a dehydrating agent, on a substrate, and drying the polymer solution to produce a phase-separated structure body having a microphase-separated structure; a step for producing a porous body by removing the phase separation agent from the phase-separated structure body; and a step for subjecting the polyamide acid in the porous body to imidization to synthesize a polyimide.

By forming a continuous phase of the polyimide porous body with a polyimide, it is possible to improve the heat resistance of such porous body.

As the polyamide acid that is a precursor of the polyimide, the known ones can be used. Specifically, the polyamide acid can be synthesized by reacting an organic tetracarboxylic acid dianhydride with a diamino compound (a diamine) in an organic solvent at 0 to 90° C. for 1 to 24 hours. The organic solvent includes a polar solvent, for example, N-methyl-2-pyrrolidone, N,N-dimethylacetamide, N,N-dimethylformamide, dimethyl sulfoxide, and the like.

The organic tetracarboxylic acid dianhydride includes, for example, pyromellitic acid dianhydride, 3,3′,4,4′-biphenyltetracarboxylic acid dianhydride, 2,2-bis(2,3-dicarboxyphenyl)-1,1,1,3,3,3-hexafluoropropane dianhydride, 2,2-bis(3,4-dicarboxyphenyl)-1,1,1,3,3,3-hexafluoropropane dianhydride, 2,2-bis(3,4-dicarboxyphenyl)-1,1,1,3,3,3-hexafluoropropane dianhydride, 3,3′, 4,4′-benzophenonetetracarboxylic acid dianhydride, bis(3,4-dicarboxyphenyl) ether dianhydride, bis(3,4-dicarboxyphenyl) sulfone dianhydride, and the like. These organic tetracarboxylic acid dianhydrides may be used alone or in combination with two or more kinds thereof. Of these, it preferable to use 3,3′,4,4′-biphenyltetracarboxylic acid dianhydride from the viewpoint of excellent strength properties of the polyimide porous body obtained.

The diamino compound includes, for example, m-phenylenediamine, p-phenylenediamine, N-silylated diamine, 3,4′-diaminodiphenyl ether, 4,4′-diaminodiphenyl ether, 4,4′-diaminodiphenyl sulfone, 3,3′-diaminodiphenyl sulfone, 2,2-bis(4-aminophenoxyphenyl)propane, 2,2-bis(4-aminophenoxypheny)hexafluoropropane, 1,3-bis(4-aminophenoxy)benzene, 1,4-bis(4-aminophenoxy)benzene, 2,4-diaminotoluene, 2,6-diaminotoluene, diaminodiphenylmethane, 4,4′-diamino-2,2-dimethylbiphenyl, 2,2-bis(trifluoromethyl)-4,4′-diaminobiphenyl, and the like. These maybe used alone or in combination with two or more kinds thereof. Of these, it is preferable to use p-phenylenediamine so as to improve the rigidity of the polyimide porous body, and it is preferable to use 4,4′-diaminodiphenyl ether so as to improve the flexibility of the polyimide porous body.

The phase separation agent is a component that constitutes a non-continuous phase of the microphase separated structure and is capable of forming the microphase separated structure when mixed with a polyamide acid. Such a phase separation agent is not particularly limited so long as it is a component that is volatilized (evaporated) by heating, decomposed (for example, carbonized) by heating, or can be extracted with a solvent.

Examples of the phase separation agent include, for example, polyalkylene glycols such as polyethylene glycol and polypropylene glycol; those polyalkylene glycols terminated at one or each end by methyl or terminated at one or each end by (meth)acrylate; urethane prepolymers; and (meth)acrylate-based compounds such as phenoxypolyethylene glycol (meth)acrylate, ε-caprolactone (meth)acrylate, trimethylolpropane tri(meth)acrylate, dipentaerythritol hexa(meth)acrylate, urethane (meth)acrylates, epoxy (meth)acrylates, and oligoester (meth)acrylates. These phase separation agents can be used alone or in combination of two or more thereof.

The molecular weight of the phase separation agent is not particularly limited, but the weight average molecular weight is preferably 100 to 10,000, more preferably 150 to 2,000, from the viewpoint that later removal procedure becomes easy. If the weight average molecular weight is less than 100, phase separation of the phase separation agent from the polyamide acid becomes difficult, whereas if the weight average molecular weight exceeds 10,000, microphase-separated structure becomes too large and it becomes difficult to remove the phase separation agent from the phase-separated structure body.

Since the average pore size, volume porosity, and pore size distribution of the polyimide porous body vary depending on the type and mixing ratio of raw materials such as polyamide acid, phase separation agent, etc.) to be used as well as on the reaction conditions such as heating temperature and heating time during the phase separation, it is preferable to select the optimal conditions after drawing a phase diagram of the system in order to obtain the desired average pore size, volume porosity, and pore size distribution.

In order to prepare the polyimide porous body having an average pore size of 0.1 to 10 μm and a volume porosity of 20 to 90%, it is preferred to use the phase separation agent in an amount of 25 to 500 parts by weight, more preferably 25 to 300 parts by weight, and furthermore preferably 50 to 200 parts by weight, based on 100 parts by weight of the polyamide acid.

As the imidization catalyst, it includes, for example, tertiary amines such as trimethylamine, triethylamine, triethylenediamine, tributylamine, dimethylaniline, pyridine, α-picoline, β-picoline, γ-picoline, isoquinoline, imidazole, 2-ethyl-4-methylimidazole, 2-phenylimidazole, N-methylimidazole, and lutidine; organic bases such as 1,5-diazabicyclo[4.3.0]nonene-5,1,4-diazabicyclo[2.2.2]octane and 1,8-diazabicyclo[5.4.0]undecene-7; and the like.

The amount added of the imidization catalyst is 0.05 to 3 molar equivalents, preferably 0.1 to 1 molar equivalent, per 1 molar equivalent of the polyamide acid unit. If the amount added of the imidization catalyst is less than 0.05 molar equivalents, there is a tendency such that it becomes difficult to obtain a desired polyimide porous body because imidization does not proceed sufficiently. On the other hand, even if the imidization catalyst is added in an amount exceeding 3 molar equivalents, there is no change in the structure and properties of the polyimide porous body. In the present invention, it should be noted that the polyamide acid unit refers to a repeating structural unit that is formed by the reaction of an organic tetracarboxylic acid dianhydride with a diamino compound.

The dehydrating agent includes, for example, an organic carboxylic acid anhydride, an N,N′-dialkylcarbodiimide, a lower fatty acid halide, a halogenated lower fatty acid anhydride, an arylphosphonic acid dihalide, a thionyl halide, and the like. These may be used alone or in combination of two or more kinds thereof. Of these, it is preferable to use an organic carboxylic acid anhydride.

As the organic carboxylic acid anhydride, it includes, for example, acetic acid anhydride, propionic acid anhydride, butyric acid anhydride, valeric acid anhydride, aromatic monocarboxylic acid anhydrides (e.g., benzoic acid anhydride, naphthoic acid anhydride, etc.), formic acid anhydride, anhydrides of aliphatic ketenes (e.g., ketene, dimethylketene, etc.), intermolecular anhydrides thereof, and mixtures thereof.

The amount added of the dehydrating agent is 0.05 to 4 molar equivalents, preferably 0.1 to 2 molar equivalents, per 1 molar equivalent of the polyamide acid unit. If the amount added of the dehydrating agent is less than 0.05 molar equivalents, imidization tends to be less likely to occur, resulting in difficulty in obtaining a polyimide porous body having a fine cell structure. On the other hand, if the amount added of the dehydrating agent exceeds 4 molar equivalents, the imidization proceeds rapidly and the polymer solution tends to become easy to gelate, and thereby to cause a trouble in the production process.

The polymer solution is prepared by mixing the each component with a solvent. As the solvent, it includes, for example, aromatic hydrocarbons such as toluene, xylene, etc.; alcohols such as methanol, ethanol, isopropyl alcohol, etc.; ketones such as methyl ethyl ketone, acetone, etc.; amides such as N-methyl-2-pyrrolidone, dimethylacetamide, dimethylformamide, etc.; and the like. The amount of the solvent to be used is about 200 to 2,000 parts by weight, preferably 300 to 1,000 parts by weight, more preferably 350 to 600 parts by weight, per 100 parts by weight of the polyamide acid.

In the method for producing a polyimide porous body of the present invention, a phase-separated structure body having a microphase-separated structure (e.g., sheet-shaped, film-shaped) is prepared by first coating the polymer solution on a substrate and drying the coated substrate.

The substrate is not particularly limited as long as it has a smooth surface, and includes, for example, plastic films, such as PET, PE, and PP; glass plates; and metal foils, such as stainless steel, copper, and aluminum. In order to produce a phase-separated structure body continuously, a belt-like base material may be used.

The method for applying a polymer solution on a substrate is not particularly limited, and a continuous coating method includes, for example, a wire bar method, a kiss coating method, and a gravure method. The method of coating in a batch system includes, for example, an applicator method, a wire bar method, and a knife coater method.

The phase-separated structure body in which the phase separation agent is microphase-separated by drying through the evaporation of the solvent of the polymer solution coated on a substrate is obtained. The temperature during evaporation (drying) of the solvent is not particularly limited and may be appropriately adjusted depending on the type of the solvents used, but it is usually 60 to 200° C. The microphase-separated structure usually takes a sea-island structure wherein the polymer component is regarded as a sea and the phase separation agent is regarded as an island.

Then, a porous body is produced by removing the phase separation agent that was microphase separated from a phase-separated structure body. Note that the phase-separated structure body may be previously detached from the substrate prior to removal of the phase separation agent.

The method to remove the phase separation agent from the phase-separated structure body is not particularly limited, but includes, for example, a method of volatilization (evaporation) by heating, a method of decomposition (carbonization) by heating, and a method of extraction with a solvent. These methods may be performed in combination.

In the case of a method for volatilizing or decomposing the phase separation agent by heating, the heating temperature can be appropriately adjusted depending on the boiling point or the decomposition temperature of the phase separation agent, but it is usually 100° C. or more, preferably 100 to 500° C., more preferably 250 to 450° C. In order to increase the removal efficiency of the phase separation agent, such removal is performed preferably under a reduced pressure (e.g. 1 mmHg or less). If the volatilization or decomposition procedure by heating and the extraction procedure are performed in combination, the residue of the phase separation agent that cannot be removed by one procedure can be completely removed by the other procedure, resulting in being able to obtain a porous body having an extremely low relative dielectric constant. It should be noted that a polyimide may be synthesized by simultaneous imidization (dehydrative ring closure reaction) of the polyamide acid in the porous body, while removing the phase separation agent by volatilization or decomposition under heating.

In the case of a method for extracting the phase separation agent with a solvent, it is necessary to use a solvent that is a good solvent for the phase separation agent and does not dissolve the polymer component, and such a solvent includes, for example, organic solvents such as toluene, ethanol, ethyl acetate, and heptane, liquefied carbon dioxide, subcritical carbon dioxide, supercritical carbon dioxide, and the like. The liquefied carbon dioxide, subcritical carbon dioxide, and supercritical carbon dioxide can remove the phase separation agent efficiently because they can easily penetrate into the phase-separated structure body.

In the case of using liquefied carbon dioxide, subcritical carbon dioxide, or supercritical carbon dioxide as a solvent, a pressure vessel is usually used. The pressure vessel that can be use includes, for example, a batch type pressure vessel and a pressure vessel provided with a pressure-resistant device for feeding and winding a sheet. The pressure vessel is usually provided with a carbon dioxide supply means constituted by pump, piping, and valve.

The temperature and pressure during the extraction of the phase separation agent with liquefied carbon dioxide, subcritical carbon dioxide or supercritical carbon dioxide may be any temperature and pressure corresponding to each state of carbon dioxide, and are usually 20 to 230° C. and 7.3 to 100 MPa, respectively, and preferably 25 to 200° C. and 10 to 50 MPa, respectively.

The extraction may be carried out by feeding/discharging continuously liquefied carbon dioxide, subcritical carbon dioxide or supercritical carbon dioxide into/from a pressure vessel in which the phase-separated structure body is placed, or may be carried out in a pressure vessel in a closed system (in a state where the charged phase-separated structure body, liquefied carbon dioxide, subcritical carbon dioxide, or supercritical carbon dioxide does not move to the outside of the vessel). In the case of using subcritical carbon dioxide or supercritical carbon dioxide, swelling of the phase-separated structure body is promoted and diffusion coefficient of the insolubilized phase separation agent is improved, resulting in efficient removal of the phase separation agent from the phase-separated structure body. In the case of using liquefied carbon dioxide, the diffusion coefficient decreases, but the phase separation agent is efficiently removed from the phase-separated structure body because of improved permeability of the liquefied carbon dioxide to the phase-separated structure body.

It is necessary to appropriately adjust the extraction time, depending on the temperature and pressure during extraction, the added amount of the phase separation agent, and the thickness of the phase-separated structure body, but the extraction time is usually 1 to 10 hours, preferably 2 to 10 hours.

On the other hand, when extraction is carried out with an organic solvent as a solvent, the deformation of the porous body as compared with the case where extraction is performed with supercritical carbon dioxide and the like can be suppressed because the phase separation agent can be removed at atmospheric pressure. It is also possible to shorten the extraction time when an organic solvent is used for the extraction. Furthermore, it is possible to continuously perform an extraction treatment of the phase separation agent by passing the phase-separated structure body sequentially in an organic solvent.

The extraction method using an organic solvent includes, for example, a method of immersing a phase-separated structure body in an organic solvent, a method of spraying an organic solvent to a phase-separated structure body, and the like. From the viewpoint of removal efficiency of the phase separation agent, such an immersing method is preferred. In addition, the phase separation agent can be removed efficiently by replacing an organic solvent over a few times or performing the extraction with stirring.

Thereafter, a polyimide porous body is produced by imidization (dehydrative ring closure reaction) of a polyamide acid in the porous body to synthesize a polyimide.

In the present invention, because an imidization catalyst and a dehydrating agent are added to the porous body, it is possible to synthesize the polyimide efficiently. The temperature in the synthesis of the polyimide is preferably 300 to 400° C.

The polyimide porous body obtained by the production method of the present invention has features of an excellent heat resistance, an extremely small average pore size, and furthermore an extremely low relative dielectric constant. Specifically, the polyimide porous body of the present invention is one having an average pore size of about 0.1 to 10 μm (preferably 0.1 to 5 μm, more preferably 0.2 to 2 μm, from the viewpoint of mechanical strength and insulating properties), a volume porosity of about 20 to 90% (preferably 40 to 90%, more preferably 50 to 85%), and a relative dielectric constant of about 1.4 to 2.0 (preferably 1.5 to 1.9).

The shape of the polyimide porous body can be changed appropriately depending on the use, but in the case of sheet, film, or the like, the thickness is usually 1 to 500 μm, preferably 10 to 150 μm, more preferably 30 to 150 μm.

In addition, the tensile elastic modulus of the polyimide porous body is preferably 1000 to 6000 MPa, more preferably 3000 to 5500 MPa.

Further, the insulation breakdown voltage of the polyimide porous body is preferably 20 kV/mm or more, more preferably 30 kV/mm or more, furthermore preferably 40 kV/mm or more. The upper limit of the insulation breakdown voltage is usually about 200 kV/mm, but it may be about 150 kV/mm in some cases.

The polyimide porous body substrate wherein a metal foil is provided on at least one side of the polyimide porous body is excellent in heat resistance, mechanical strength, and insulating properties, and is suitably used as parts, such as circuit boards, printed circuit boards, etc., for electronic/electrical devices, electronic parts, etc.

### EXAMPLES

The present invention will be described below by way of Examples, without intending to limit the present invention thereto in any way.

### [Measurement and Evaluation Method]

### (Measurement of Average Pore Size)

The polyimide porous body that had been prepared was cooled with liquid nitrogen and cut perpendicularly to the sheet surface by using a knife to prepare a sample. The cut surface of the sample was subjected to Au evaporation and the cut surface was observed with a scanning electron microscope (SEM). Its image was binarized with the image processing software (“WinROOF”, manufactured by Mitani CORPORATION) to separate into the cell portion and the resin portion, and the size of the cell was measured. The respective sizes for 50 cells were measured and the average value was regarded as the average pore size.

### (Measurement of Volume Porosity)

The specific gravities of the polyimide porous body and non-porous body prepared were measured respectively with an electronic gravimeter (MD-3005, manufactured by Alfa Mirage Co., Ltd.), and the volume porosity was calculated from the following equation:

Volume porosity (%)={1−(Specific gravity of polyimide porous body)/(Specific gravity of non-porous body)}×100

### (Measurement of Tensile Elastic Modulus)

The polyimide porous body prepared was punched into a sample of a dumbbell shape No. 3 according to the standard as defined in JIS K6251. The tensile elastic modulus of the sample was measured by performing a tensile test at a speed of 100 mm/min. A tension/compression tester was used as a measuring instrument (Tensilon RTG1210, manufactured by A&D Company, Limited). In order to correct the volume porosity of the sample, the bulk elastic modulus was calculated using the following equation:

Bulk elastic modulus (MPa)=Measurement value/(1−Volume porosity/100).

### (Evaluation of Insulation Breakdown Voltage)

By the method in accordance with the standard as defined in JIS C2110, the insulation breakdown voltage of the prepared polyimide porous body was measured at a pressure rise rate of 1 kV/sec.

### (Measurement of Relative Dielectric Constant)

The relative dielectric constant was determined by measuring a complex dielectric constant at a frequency of 1 GHz by the cavity resonator perturbation method and defining its real part as the relative dielectric constant. A strip-shaped sample (sample size: 2 mm×70 mm length) was used for the measurement with a measurement equipment such as a cylindrical cavity resonator (“Network Analyzer N5230C”, manufactured by Agilent Technologies, Inc.; “Cavity Resonator 1 GHz”, manufactured by Kanto Electronic Application and Development Inc.).

### Example 1

N-Methyl-2-pyrrolidone (NMP) 785.3 g, p-phenylenediamine (PDA) 44.1 g, and 4,4′-diaminodiphenyl ether (DDE) 20.4 g were added to a 1000 ml four-necked flask, and the mixture was dissolved while stirring at a normal temperature. Then, 3,3′,4,4′-biphenyltetracarboxylic acid dianhydride (BPDA) 150.2 g was added thereto, and the mixture was reacted at 25° C. for one hour, thereby to obtain a polyamide acid solution having a solution viscosity of 160 Pa·s (solid content concentration: 20 wt %) as measured with a type B viscometer by heating at 75° C. for 25 hours. To the polyamide acid solution were added 2-methylimidazole of 0.832 g (0.2 molar equivalents per 1 molar equivalent of polyamide acid unit) as an imidization catalyst and benzoic acid anhydride of 2.32 g (0.2 molar equivalents per 1 molar equivalent of polyamide acid unit) as a dehydrating agent.

To the polyamide acid solution, 20 parts by weight of polypropylene glycol having a weight average molecular weight of 400, based on 100 parts by weight of the polyamide acid solution, were added, and the mixture was stirred to obtain a clear homogenous polymer solution. By using an applicator, this polymer solution was coated on a PET film, and dried at 85° C. for 15 minutes to remove NMP by evaporation, thereby to prepare a phase-separated structure body having a micro-phase separated structure. This phase-separated structure body was placed in a pressure vessel of 500 cc, pressurized to 25 MPa under an atmosphere of 25° C., and CO₂ was injected thereto at a flow rate of about 15 L/min as the gas amount while maintaining the pressure. After exhaust, a porous body was obtained by performing a procedure of extracting the polypropylene glycol for 5 hours. Then the porous body was heated at 340° C. for 1 hour to prepare a polyimide porous body.

### Example 2

A polyimide porous body was prepared in the same manner as in Example 1, except that a polypropylene glycol having a weight average molecular weight of 250 was added in place of the polypropylene glycol having a weight average molecular weight of 400 in Example 1.

### Example 3

A polyimide porous body was prepared in the same manner as in Example 1, except that in Example 1, isoquinoline of 1.308 g (0.2 molar equivalents per 1 molar equivalent of polyamide acid unit) as an imidization catalyst was added in place of 2-methylimidazole, and a polypropylene glycol having a weight average molecular weight of 250 was added in place of the polypropylene glycol having a weight average molecular weight of 400.

### Example 4

A polyimide porous body was prepared in the same manner as in Example 1, except that in Example 1, triethylamine of 1.026 g (0.2 molar equivalents per 1 molar equivalent of polyamide acid unit) as an imidization catalyst was added in place of 2-methylimidazole, and a polypropylene glycol having a weight average molecular weight of 250 was added in place of the polypropylene glycol having a weight average molecular weight of 400.

### Example 5

A polyimide porous body was prepared in the same manner as in Example 1, except that in Example 1, isoquinoline of 1.308 g (0.2 molar equivalents per 1 molar equivalent of polyamide acid unit) was added as an imidization catalyst in place of 2-methylimidazole; acetic acid anhydride of 1.034 g (0.2 molar equivalents per 1 molar equivalent of polyamide acid unit) was added as a dehydrating agent in place of benzoic acid anhydride; and a polypropylene glycol having a weight average molecular weight of 250 was added in place of the polypropylene glycol having a weight average molecular weight of 400.

### Example 6

A polyimide porous body was prepared in the same manner as in Example 1, except that in Example 1, acetic acid anhydride of 1.034 g (0.2 molar equivalents per 1 molar equivalent of polyamide acid unit) was added as a dehydrating agent in place of benzoic acid anhydride, and a polypropylene glycol having a weight average molecular weight of 250 was added in place of the polypropylene glycol having a weight average molecular weight of 400.

### Example 7

A polyimide porous body was prepared in the same manner as in Example 1, except that in Example 1, triethylamine of 1.026 g (0.2 molar equivalents per 1 molar equivalent of polyamide acid unit) was added as an imidization catalyst in place of 2-methylimidazole; acetic acid anhydride of 1.034 g (0.2 molar equivalents per 1 molar equivalent of polyamide acid unit) was added as a dehydrating agent in place of benzoic acid anhydride; and a polypropylene glycol having a weight average molecular weight of 250 was added in place of the polypropylene glycol having a weight average molecular weight of 400.

### Comparative Example 1

A polyimide porous body was prepared in the same manner as in Example 1, except that the imidization catalyst and the dehydrating agent were not added to the polyamide acid solution in Example 1.

### Comparative Example 2

A polyimide porous body was prepared in the same manner as in Example 1, except that in Example 1, the imidization catalyst and the dehydrating agent were not added to the polyamide acid solution, and a polypropylene glycol having a weight average molecular weight of 250 was added in place of the polypropylene glycol having a weight average molecular weight of 400.

TABLE 1

| | | Example | Example | Example | Example | Example | Example | Example | Comparative | Comparative |
|---|---|---|---|---|---|---|---|---|---|---|
| | | 1 | 2 | 3 | 4 | 5 | 6 | 7 | Example 1 | Example 2 |
| Imidization catalyst | 2-Methylimidazole | 0.2 | 0.2 | | | | 0.2 | | | |
| (molar equivalent) | Isoquinoline | | | 0.2 | | 0.2 | | | | |
| | Triethylamine | | | | 0.2 | | | 0.2 | | |
| Dehydrating agent | Benzoic acid | 0.2 | 0.2 | 0.2 | 0.2 | | | | | |
| (molar equivalent) | anhydride | | | | | | | | | |
| | Acetic acid | | | | | 0.2 | 0.2 | 0.2 | | |
| | anhydride | | | | | | | | | |
| Polypropylene glycol | Weight average | 20 | | | | | | | 20 | |
| (part by weight) | molecular weight of | | | | | | | | | |
| | 400 | | | | | | | | | |
| | Weight average | | 20 | 20 | 20 | 20 | 20 | 20 | | 20 |
| | molecular weight of | | | | | | | | | |
| | 250 | | | | | | | | | |

| | | | | | | | | | |
|---|---|---|---|---|---|---|---|---|---|
| Average pore size (μm) | 3.0 | 1.5 | 4.7 | 3.4 | 4.8 | 4.5 | 4.4 | 6.4 | 6.1 |
| Volume porosity (%) | 83 | 68 | 63 | 68 | 58 | 71 | 67 | 68 | 67 |
| Tensile elastic modulus (MPa) | 3653 | 5266 | 2879 | 2990 | 3878 | 3166 | 3078 | 1853 | 4061 |
| Insulation breakdown voltage (kV/mm) | 40 | 127 | 31 | 35 | 48 | 28 | 26 | 20 | 25 |
| Relative dielectric constant | 1.6 | 1.9 | 2.0 | 1.9 | 2.1 | 1.8 | 2.0 | 2.0 | 2.2 |

### INDUSTRIAL APPLICABILITY

The polyimide porous body of the present invention is suitably used for circuit boards, printed circuit boards, etc., in electronic/electrical devices, or electronic parts, etc.

1. A method for producing a polyimide porous body, comprising a step for applying a polymer solution containing a polyamide acid, a phase separation agent for separating the phases of the polyamide acid, an imidization catalyst, and a dehydrating agent, on a substrate, and drying the polymer solution to produce a phase-separated structure body having a microphase-separated structure; a step for producing a porous body by removing the phase separation agent from the phase-separated structure body; and a step for subjecting the polyamide acid in the porous body to imidization to synthesize a polyimide.

2. The method for producing a polyimide porous body according to claim 1, wherein the phase separation agent is removed by solvent extraction.

3. The method for producing a polyimide porous body according to claim 2, wherein the solvent is liquefied carbon dioxide, subcritical carbon dioxide, or supercritical carbon dioxide.

4. The method for producing a polyimide porous body according to claim 1, wherein the phase separation agent is removed by heating.

5. The method for producing a polyimide porous body according to claim 1, wherein the temperature in the step for synthesizing a polyimide is 300 to 400° C.

6. A polyimide porous body produced by claim 1.

7. The polyimide porous body according to claim 6, wherein the average pore size is 0.1 to 10 μm, the volume porosity is 20 to 90%, and the relative dielectric constant is 1.4 to 2.0.

8. A polyimide porous body substrate having a metal foil on at least one side of the polyimide porous body according to claim 6.
